(19) United States
(12) Patent Application Publication
(10) Pub. No.: US 2013/0279117 A1
(43) Pub. Date: Oct. 24, 2013

(54) Heat Dissipating Structure

(71) Applicant: DELTA ELECTRONICS, INC., Taoyuan Hsien (TW)

(72) Inventor: Hung-Chuan CHEN, Taoyuan Hsien (TW)

(73) Assignee: DELTA ELECTRONICS, INC., Taoyuan Hsien (TW)

(21) Appl. No.: 13/853,818

(22) Filed: Mar. 29, 2013

(30) Foreign Application Priority Data
Apr. 24, 2012 (TW) 101114454

(51) Int. Cl. H05K 7/20

(52) U.S. Cl. CPC H05K 7/2039
USPC 361/704

(57) ABSTRACT

A heat dissipating structure includes a heat dissipating element, a first insulating element, a second insulating element, an electronic element and at least one fixing element. The first insulating element is disposed on one side of the heat dissipating element, while the second insulating element is disposed on another side of the heat dissipating element. The electronic element is disposed on the first insulating element. The fixing element fixes the electronic element on the heat dissipating element.

### CROSS REFERENCE TO RELATED APPLICATIONS

This Non-provisional application claims priority under 35 U.S.C. §119(a) on Patent Application No(s). 101114454 filed in Taiwan, Republic of China on Apr. 24, 2012, the entire contents of which are hereby incorporated by reference.

### BACKGROUND OF THE INVENTION

1. Field of Invention

The present invention relates to a heat dissipating structure.

2. Related Art

Since various novel electronic apparatuses have more and more powerful functions and performances, the accompanying heat as the electronic apparatuses are operating is accordingly larger. In general, a heat dissipating structure is installed in an electronic apparatus for dissipating the generated heat.

FIG. 1A is an exploded view of a conventional heat dissipating structure and FIG. 1B is a sectional view along a line A-A of the heat dissipating structure 1. As shown in FIGS. 1A and 1B, the conventional heat dissipating structure 1 includes a heat dissipating plate 11, an insulating plate 12, an electronic element 13, an insulating member 14, and a screw 15. The insulating plate 12 is disposed between the heat dissipating plate 11 and the electronic element 13 for preventing the short circuit of the heat dissipating plate 11 and the electronic element 13. In addition, the insulating member 14 is disposed between the electronic element 13 and the screw 15 for preventing the short circuit of the electronic element 13, the screw 15, and the heat dissipating plate 11 along the direction H.

In the heat dissipating structure 1, the neck 141 of the insulating member 14 has a length D1 for providing an insulation space to the electronic element 13 in the direction FL However, since the insulating plate 12, the electronic element 13 and the insulating member 14 are all positioned at the same side, the neck 141 of the insulating member 14 must insert into the screw hole 111, which is configured to fixing the screw 15. Unfortunately, the thickness of the neck 141 is restricted by the dimension of the screw hole 111, so the insulating member 14 can not provide longer insulation space. In other words, the insulating space along the direction H may be insufficient, so that the heat dissipating plate 11 and the electronic element 13 is shorted, thereby generating sparks or inducing other electrical issues.

Therefore, it is an important subject to provide a heat dissipating structure that can increase insulation space.

### SUMMARY OF THE INVENTION

In view of the foregoing subject, an objective of the present invention is to provide a heat dissipating structure that can increase insulation space.

To achieve the above objective, the present invention discloses a heat dissipating structure, which comprises a heat dissipating element, a first insulating element, a second insulating element, an electronic element, and at least one fixing element. The first insulating element is disposed on one side of the heat dissipating element, and the second insulating element is disposed on another side of the heat dissipating element opposite to the first insulating element. The electronic element is disposed on the first insulating element. The fixing element is configured for fixing the electronic element on the heat dissipating element.

In one embodiment, the second insulating element has a limiting portion, which is polygonal.

In one embodiment, the second insulating element has a stopping portion and/or a receiving portion.

As mentioned above, the heat dissipating structure of the invention has a first insulating element and a second insulating element disposed at opposite sides of the electronic element. Accordingly, the second insulating element can be fixed without using the conventional component having the neck structure for passing through the through hole to fix the electronic element. In other words, the second insulating element is used to define the insulation space between the heat dissipating element 21 and the electronic element 24. For example, the defined insulation space is the radial length of the bottom of the second insulating element. Accordingly, the insulation space can be easily changed by designing the dimension of the second insulating element depending on various requirements.

### BRIEF DESCRIPTION OF THE DRAWINGS

The present invention will become more fully understood from the subsequent detailed description and accompanying drawings, which are given by way of illustration only, and thus are not limitative of the present invention, and wherein:

FIG. 1A is an exploded view of a conventional heat dissipating structure;

FIG. 1B is a sectional view along the line A-A of the heat dissipating structure of FIG. 1A;

FIG. 2A is an exploded view of a heat dissipating structure according to an embodiment of the invention;

FIG. 2B is a sectional view along the line A-A of the heat dissipating structure of FIG. 2A;

FIG. 3A is an exploded view of another heat dissipating structure according to the embodiment of the invention;

FIG. 3B is a sectional view along the line A-A of the heat dissipating structure of FIG. 3A;

FIG. 4A is an exploded view of another heat dissipating structure according to the embodiment of the invention; and

FIG. 4B is a sectional view along the line A-A of the heat dissipating structure of FIG. 4A.

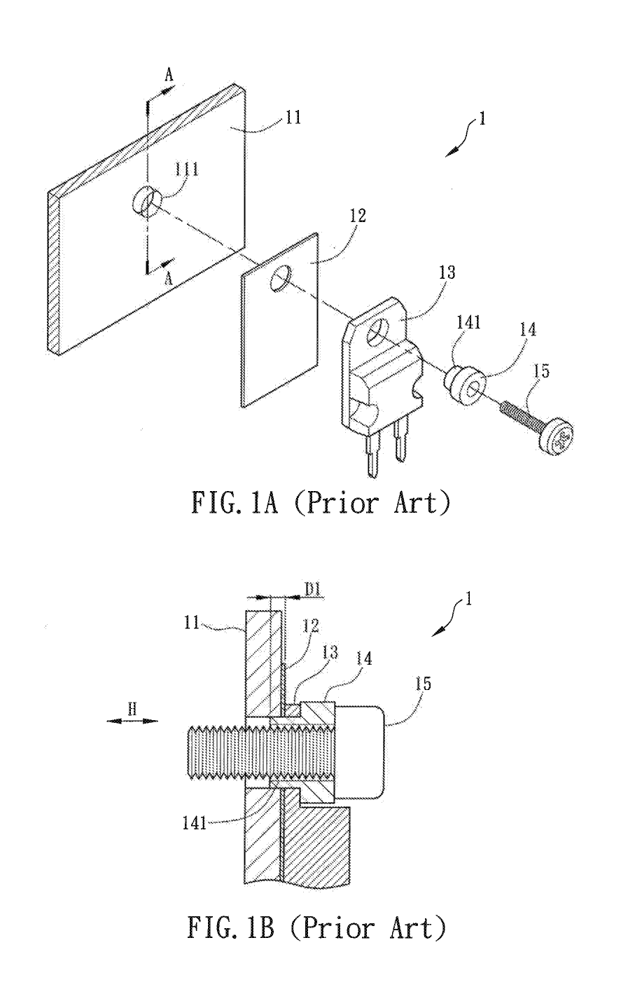

### DETAILED DESCRIPTION OF THE INVENTION

The present invention will be apparent from the following detailed description, which proceeds with reference to the accompanying drawings, wherein the same references relate to the same elements.

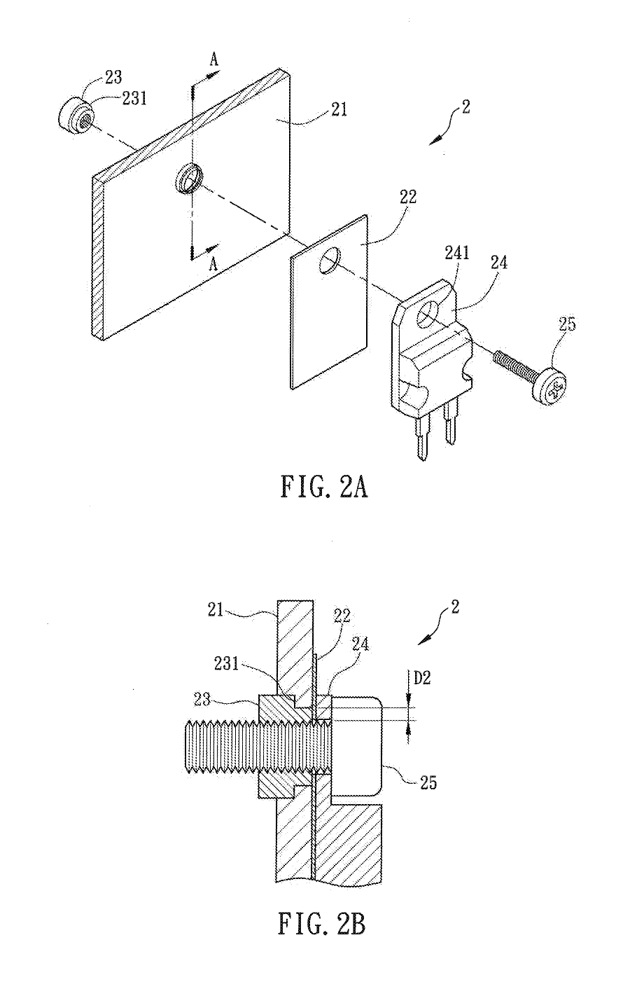

FIG. 2A is an exploded view of a heat dissipating structure 2 according to an embodiment of the invention, and FIG. 2B is a sectional view along a line A-A of the heat dissipating structure 2. The heat dissipating structure 2 can he applied to a power supplier or other electronic apparatuses. As shown in FIGS. 2A and 2B, the heat dissipating structure 2 includes a heat dissipating element 21, a first insulating element 22, a second insulating element 23, an electronic element 24, and at least a fixing element 25.

The heat dissipating element 21 can be a heat sink, a heat dissipating plate, or any component with heat dissipating function. The first insulating element 22 can be an insulating plate or any component with insulating function and is disposed at one side of the heat dissipating element 21.

The second insulating element 23 can be an insulating bushing or any component with insulating function. The first insulating element 22 and the second insulating element 23 are disposed at opposite sides of the heat dissipating element 21. Besides, in order to firmly fixing the second insulating element to the heat dissipating element 21, the second insulating element 23 has a stopping portion 231 through which the second insulating element 23 can contact against the heat dissipating element 21 and then fixed. Of course, this is not to limit the invention, and for example, the second insulating element 23 may have a cylindrical structure.

The electronic element 24, such as an IC chip, is disposed on the first insulating element 22. The fixing element 25, such as a screw or any other component with the fixing function, fixes the electronic element 24 on the heat dissipating element 21. In this embodiment, the fixing element 25 is, for example but not limited to, a screw.

Since the first insulating element 22 and the second insulating element 23 are disposed at opposite sides of the heat dissipating element , the second insulating element 23 can be fixed without using the conventional component having the neck structure for passing through the through hole 241 to fix the electronic element 24. In other words, the second insulating element 23 is used to define the insulation space between the heat dissipating element 21 and the electronic element 24. In this embodiment, the defined insulation space is the radial length D2 of the bottom of the second insulating element 23. Accordingly, the insulation space can be easily changed by designing the dimension of the second insulating element 23 depending on various requirements.

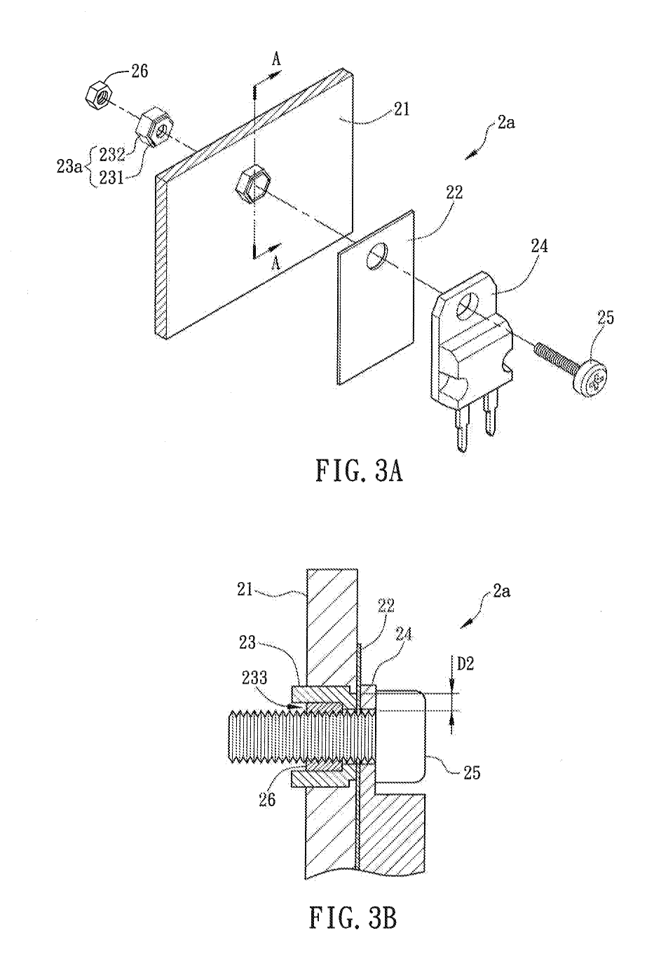

FIG. 3A is an exploded view of another heat dissipating structure 2a according to the embodiment of the invention, and FIG. 3B is a sectional view along the line A-A of the heat dissipating structure 2a. Different from the previously mentioned heat dissipating structure 2, as shown in FIGS. 3A and 3B, the second insulating element 23a of the heat dissipating structure 2a further includes a limiting portion 232 and a receiving portion 233, and two fixing elements 25 and 26 are configured for fixing. The limiting portion 232 can be polygonal and is hexagonal in this case. To be noted, the limiting portion 232 can provide the limiting function by different ways. For example, the limiting portion may have a protrusion for limiting. In addition, the fixing element 26 is, for example, a screw nut and is disposed in the receiving portion 233 for fixing with the fixing element 25 by screwing.

The configuration of the limiting portion 232 can enhance the limiting function of the second insulating element 23a, so that the second insulating element 23a will not be easily loosened. Moreover, the fixing elements 25 and 26 are connected to provide sufficient fixing. If the fixing element 25 is directly screwed to the second insulating element 23a, the second insulating element 23a made of the material with insufficient hardness is easily damaged. This configuration of the invention can prevent the damage of the second insulating element 23a and further enhance the strength of the entire structure.

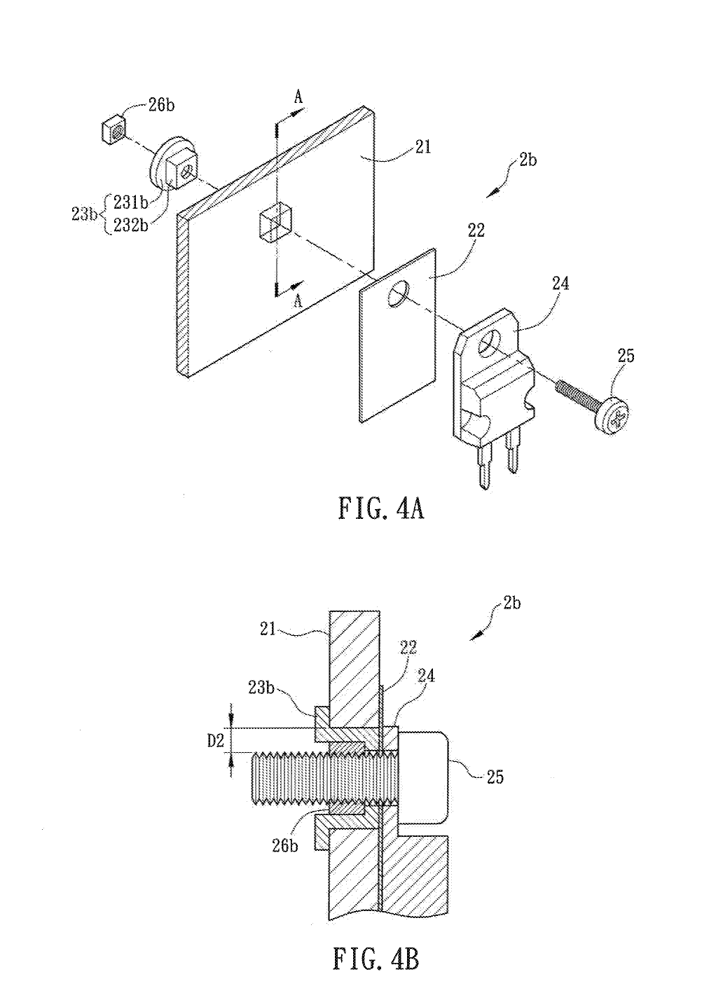

FIG. 4A is an exploded view of another heat dissipating structure 2b according to the embodiment of the invention, and FIG. 4B is a sectional view along the line AA of the heat dissipating structure 2b. Different from the previous embodiments, as shown in FIG. 4A and 4B, the second insulating element 23b of the heat dissipating structure 2b includes a circular stopping portion 23 I b and a quadrilateral limiting portion 232b. In this embodiment, the second insulating element 23b can have different configurations with respect to different demands.

In summary, the heat dissipating structure of the invention has a first insulating element and a second insulating element disposed at opposite sides of the electronic element. Accordingly, the second insulating element can be fixed without using the conventional component having the neck structure for passing through the through hole to fix the electronic element. In other words, the second insulating element is used to define the insulation space between the heat dissipating element 21 and the electronic element 24. For example, the defined insulation space is the radial length of the bottom of the second insulating element. Accordingly, the insulation space can be easily changed by designing the dimension of the second insulating element depending on various requirements.

Although the present invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the present invention.

What is claimed is:

1. A heat dissipating structure, comprising:
a heat dissipating element;
a first insulating element disposed on one side of the heat dissipating element;
a second insulating element disposed on another side of the heat dissipating element opposite to the first insulating element;
an electronic element disposed on the first insulating element; and
at least one fixing element for fixing the electronic element on the heat dissipating element.

2. The heat dissipating structure of claim 1, wherein the second insulating element has a limiting portion.

3. The heat dissipating structure of claim 2, wherein the limiting portion is polygonal.

4. The heat dissipating structure of claim 1, wherein the second insulating element has a stopping portion.

5. The heat dissipating structure of claim 1, wherein the second insulating element has a receiving portion.
